(19) United States
(12) Patent Application Publication
(10) Pub. No.: US 2007/0187822 A1
(43) Pub. Date: Aug. 16, 2007

(54) Patterned gold bump structure for semiconductor chip

(76) Inventors: Yi-Cheng Chen, Hsin-Chu (TW); Chun-Ping Hu, Hsin-Chu (TW); Chien-Wen Tsai, Hsin-Chu (TW)

Correspondence Address: G. LINK CO., LTD, 3550 Bell Road, MINOOKA, IL, 60447, US

(21) Appl. No.: 11/353,068

(22) Filed: Feb. 14, 2006

(51) Int. Cl. H01L 23/48; H01L 23/52; H01L 29/40

(52) U.S. Cl. 257/737

(57) ABSTRACT

A patterned gold bump structure for a semiconductor chip comprises at least a patterned gold bump disposed on an insulating layer of a semiconductor chip, wherein the gold bump is used as a circuit component or a passing line. In some embodiments, the circuit component is a capacitor, a resistor, or an inductor.

### FIELD OF THE INVENTION

The present invention relates to a structure of gold bump for a semiconductor chip, and more particularly, to a patterned gold bump structure applied to a semiconductor chip.

### BACKGROUND OF THE INVENTION

A conventional semiconductor chip 1 comprises a chip 25, an insulating layer 23, a plurality of aluminum (Al) pads 21, and a plurality of gold bumps 10 as shown in FIG. 1. The gold bumps 10 are formed respectively corresponding to the Al pads 21. Each gold bump 10 is isolated from other gold bumps 10. A novel structure of gold bumps 10 is thus disclosed by the applicant and could be served as a portion of the circuit design.

### SUMMARY OF THE INVENTION

It is a primary object of the invention to provide a patterned gold bump structure, which can be used as a part of the circuit.

In accordance with the objects of the invention, a patterned gold bump structure for a semiconductor chip is provided. The structure comprises at least a patterned gold bump disposed on an insulating layer of a semiconductor chip, wherein the gold bump is used as a circuit component or a passing line. In some embodiments, the circuit component is a capacitor, a resistor, or an inductor.

### BRIEF DESCRIPTION OF THE DRAWINGS

The foregoing aspects, as well as many of the attendant advantages and features of this invention will become more apparent by reference to the following detailed description, when taken in conjunction with the accompanying drawings, wherein:

FIG. 1 shows a conventional gold bump structure disposed on a semiconductor chip;

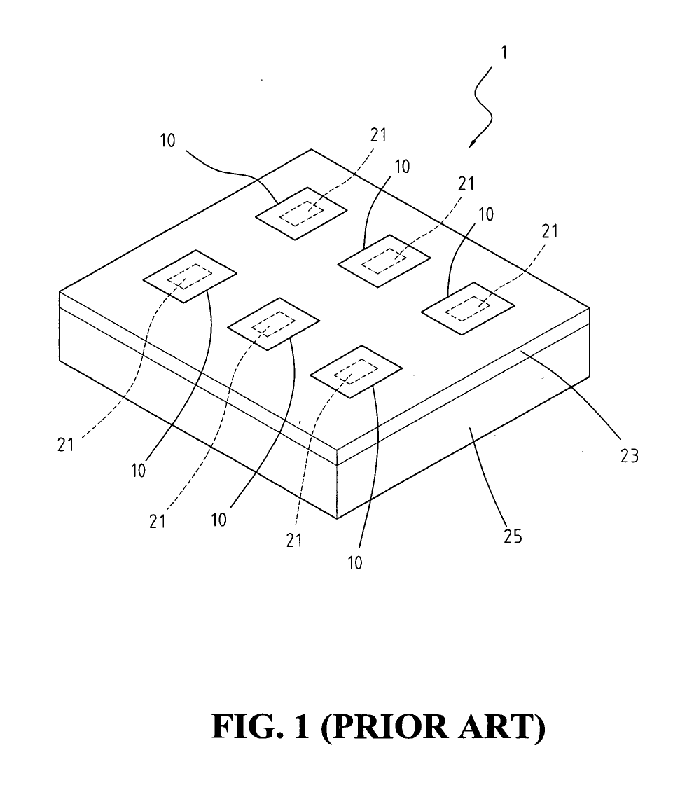

FIG. 2 illustrates a patterned gold bump structure according to the first embodiment of the invention;

FIG. 3 illustrates a patterned gold bump structure according to the second embodiment of the invention;

FIG. 4 illustrates a patterned gold bump structure according to the third embodiment of the invention; and

FIG. 5 illustrates a patterned gold bump structure according to the fourth embodiment of the invention.

### DETAILED DESCRIPTION OF THE INVENTION

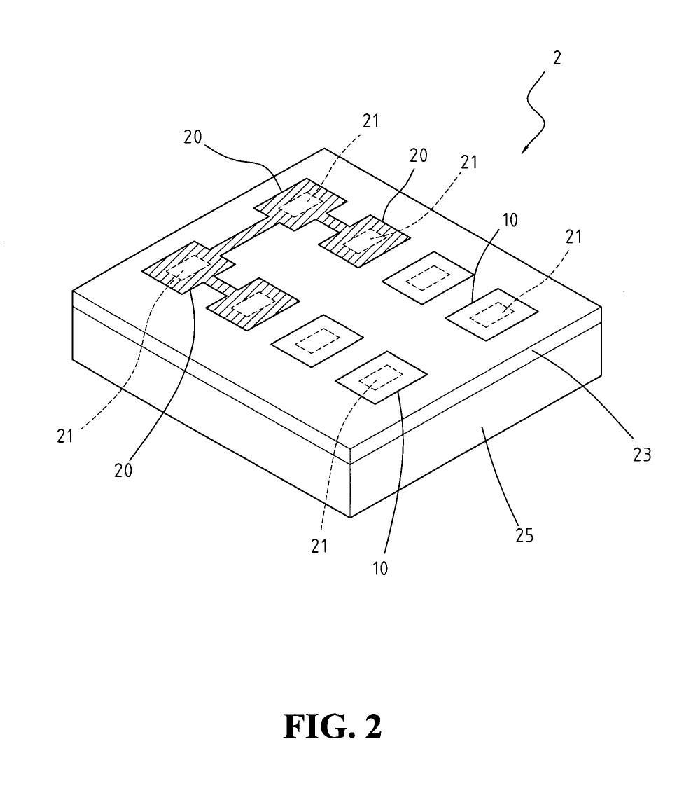

FIG. 2 illustrates a patterned gold bump structure according to the first embodiment of the invention. The patterned gold bump structure is applied to a semiconductor chip 2. The semiconductor chip 2 includes a chip 25, an insulating layer 23 and a plurality of Al pads 21. Optionally, traditional gold bumps 10 are disposed on the semiconductor chip 2. In this embodiment, a plurality of patterned gold bumps 20 function as passing lines. The patterned gold bumps 20 are connected with one another as illustrated in shaded area of FIG. 2. Since the patterned gold bumps 20 are conductive, they can serve as passing lines of signals. Furthermore, the patterned gold bumps 20 may be formed corresponding to the Al pads 21 on the semiconductor chip 2.

The patterned gold bumps 20 are characteristic of low resistance, and therefore RC delays of the passing lines in critical paths, which are made from the patterned gold bumps 20, are reduced. Accordingly, the patterned gold bumps 20 can be applied to the passing lines of high-frequency or care-timing signals, so as to enhance the performance of the integrated circuit (IC).

Because source driver IC has large volume and a rectangular form, IR drop of power passing lines in such IC is usually high. As a result, the pitch of the passing line is widened for low IR drop, and the area of source driver IC is occupied. Fortunately, the patterned gold bumps 20 of the invention can be used as portion of the power passing lines. The effective area of source driver IC is thus increased. Also, IR drop is decreased due to low resistance of the patterned gold bumps 20, and the performance of source driver IC is improved.

The conventional method to fabricate power passing lines for electrostatic discharge (ESD) includes surrounding the outer area of source driver IC that is in the form of rectangle, such that ESD is not high. Hence, additional areas are deployed for thunder to increase ESD. Since the patterned gold bumps 20 can further serve as power passing lines for ESD, the space of source driver IC is saved and ESD is also increased. In the trend to develop IC with high pin counts, the aforementioned advantages are more apparent for such long IC because the patterned gold bumps 20 occupy less space and aid in increasing ESD.

Sometimes, more than one passing lines of source driver IC are required by the whole system. The common way to meet the requirement is to deploy the lines passing through the inner of IC, which wastes on the area thereof. Furthermore, the effective area of IC is decreased when passing lines are wider for low IR drop or RC delay. The area of IC can be utilized more efficiently by substituting the patterned gold bumps 20 for the traditional passing lines. Signal quality of the passing lines made from the patterned gold bumps 20 is also better.

Additionally, the patterned gold bumps 20 may serve as the auxiliaries of film drawing. For example, the patterned gold bump 20 is applicable when a pad of Function Pin A is positioned at location Y for connection of film but is desired to be positioned at location X for better performance of IC. Under the circumstances, the pad of Function Pin A is deployed at location X, while the passing line of the patterned gold bump 20 is pulled to location Y for connection of film.

The patterned gold bumps 20 of FIG. 2 further provide various designs for the inner circuit of the chip 25. The inner circuit may be modified its function, for example, by connecting the patterned gold bumps 20 to high voltage pins or by shorting some of the patterned gold bumps 20.

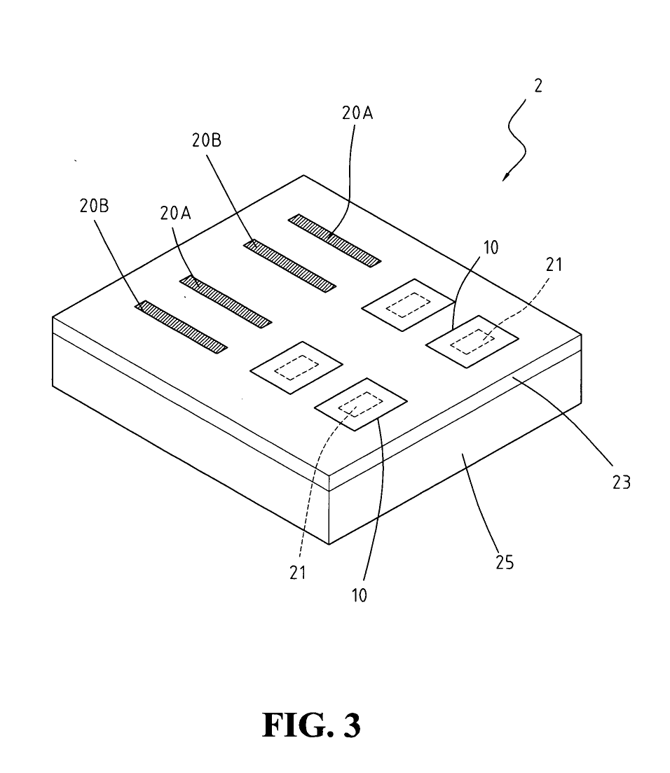

FIG. 3 illustrates a patterned gold bump structure according to the second embodiment of the invention. The semiconductor chip 2 includes a chip 25, an insulating layer 23 and a plurality of Al pads 21. Optionally, traditional gold bumps 10 are disposed on the semiconductor chip 2. In this embodiment, a pair of patterned gold bumps 20A and 20B are disposed in parallel to form a capacitor as shown in the shaded part of FIG. 3. Since the patterned gold bumps 20A and 20B are conductive, they can be used as a plate of the capacitor. For instance, a capacitor is composed of the patterned gold bumps 20A, 20B, and a dielectric layer disposed there-between. The pair of the patterned gold bumps 20A and 20B may be formed on an upper surface of the insulating layer 23.

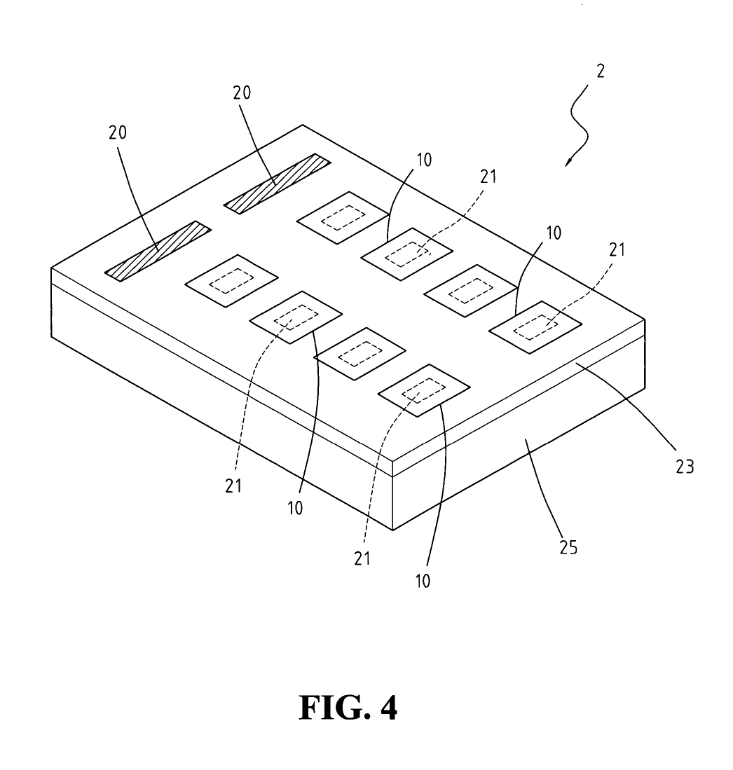

FIG. 4 illustrates a patterned gold bump structure according to the third embodiment of the invention. The semiconductor chip 2 includes a chip 25, an insulating layer 23 and a plurality of Al pads 21. Optionally, traditional gold bumps 10 are disposed on the semiconductor chip 2. In this embodiment, a plurality of patterned gold bumps 20 serve as resistors as shown in shadows of FIG. 4. The resistors are manufactured by, for example, forming the material of patterned gold bumps 20 containing resistant substances on the upper surface of the insulating layer 23.

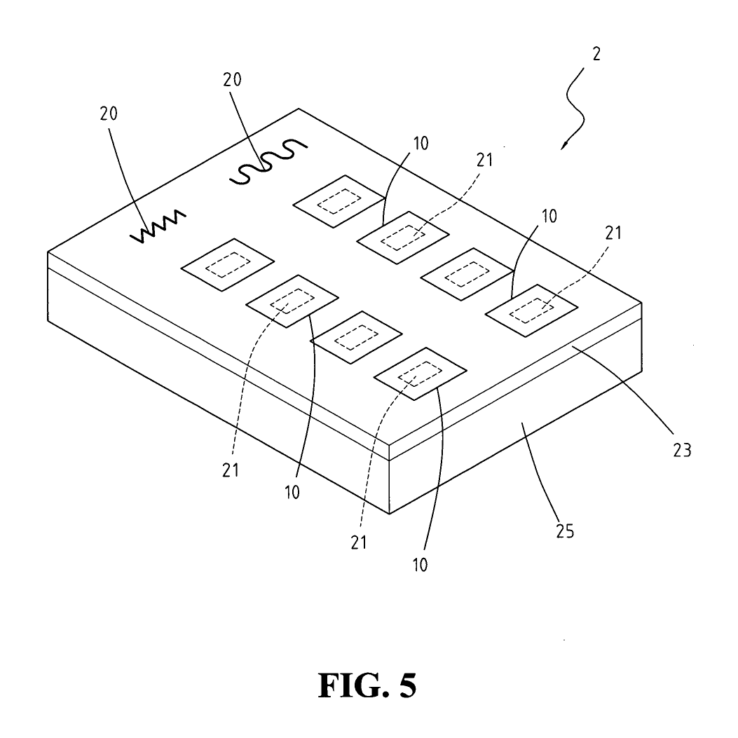

FIG. 5 illustrates a patterned gold bump structure according to the fourth embodiment of the invention. The semiconductor chip 2 includes a chip 25, an insulating layer 23 and a plurality of Al pads 21. Optionally, traditional gold bumps 10 are disposed on the semiconductor chip 2. In this embodiment, a plurality of patterned gold bumps 20 are used as inductors. Because the patterned gold bumps 20 are conductive and include zigzag geometrical patterns, they can serve as inductors.

The aforementioned embodiments may be employed on the semiconductor chip 2 spontaneously. Therefore, those devices like capacitors, resistors or inductors are formed on the insulating layer 23 of the semiconductor chip 2, and these devices are electrically connected with one another by means of the passing lines of the patterned gold bumps.

The patterned gold bump structure of the present invention can be used as a portion of circuits, which is different and superior to prior arts.

While the invention has been particularly shown and described with reference to the preferred embodiments thereof, these are, of course, merely examples to help clarify the invention and are not intended to limit the invention. It will be understood by those skilled in the art that various changes, modifications, and alterations in form and details may be made therein without departing from the spirit and scope of the invention, as set forth in the following claims.

What is claimed is:

1. A patterned gold bump structure for a semiconductor chip, the structure comprising at least a patterned gold bump disposed on an insulating layer of a semiconductor chip, wherein said patterned gold bump is used as a circuit component or a passing line.

2. The structure of claim 1, wherein a portion of said patterned gold bump is formed corresponding to an aluminum (Al ) pad of the semiconductor chip.

3. The structure of claim 1, wherein a portion of said patterned gold bump is formed on an upper surface of the insulating layer of the semiconductor chip.

4. The structure of claim 3, wherein a portion of said patterned gold bump is isolated from any aluminum pad on the semiconductor chip.

5. The structure of claim 1, wherein said patterned gold bump includes a passing line passing through, and contacting another patterned gold bump.

6. The structure of claim 1, wherein two of the patterned gold bumps are disposed in parallel to form a capacitor.

7. The structure of claim 1, wherein said patterned gold bump is a resistor.

8. The structure of claim 1, wherein said patterned gold bump is an inductor.

9. The structure of claim 1, wherein said patterned gold bump includes a geometrical pattern.
